(19) United States
(12) Patent Application Publication
(10) Pub. No.: US 2012/0070925 A1
(43) Pub. Date: Mar. 22, 2012

(54) Method for Producing a Thin-Film Semiconductor Chip

(75) Inventors: Andreas Ploessl, Regensburg (DE); Wilhelm Stein, Lindau (DE)

(73) Assignee: Osram Opto Semiconductors GmbH

(21) Appl. No.: 13/234,599

(22) Filed: Sep. 16, 2011

Related U.S. Application Data
(63) Continuation of application No. 11/576,343, filed on Mar. 19, 2008.

(30) Foreign Application Priority Data
Sep. 29, 2004 (DE) 102004047392.7
Dec. 22, 2004 (DE) 102004061865.8

(51) Int. Cl. H01L 33/46

(52) U.S. Cl. 438/29; 257/E33.067

(57) ABSTRACT

Manufacturing methods for a thin-film semiconductor chip based on a III/V-III/V semiconductor compound material and capable of generating electromagnetic radiation. In one method, a succession of active layers is applied to a growth substrate. Applied to the reverse side of the active layers is a dielectric layer. Laser energy is introduced into a defined volumetric section of the dielectric layer to form an opening. Subsequently, a metallic layer is applied to form a succession of reflective layers, to fill the opening with metallic material and to create a reverse-side electrically conductive contact point to the reverse side of the succession of active layers. Pursuant to another method, a succession of reflective layers is applied to the active layers and laser energy is applied to a volumetric section of the reflective layers, to create a reverse-side electrically conductive contact point.

### CROSS-REFERENCE TO RELATED APPLICATIONS

This application is a continuation (and claims the benefit of priority under 35 U.S.C. §120) of U.S. patent application Ser. No. 11/576,343, with a filing date, under 35 U.S.C. §371(c), of Mar. 19, 2008, which is a national stage application, under 35 U.S.C. §371, of International Application No. PCT/DE05/01684, filed Sep. 23, 2005, which claims the benefit of priority of German Application Nos. 102004047392.7 and 102004061865.8, filed on Sep. 29, 2004 and Dec. 22, 2004, respectively. The disclosure of each of these prior applications is incorporated herein by reference in its entirety.

This invention pertains to a process for the manufacture of a thin-film semiconductor chip.

### BACKGROUND

Thin-film semiconductor chips are known, for example, from publication EP 0 905 797 A2. For the manufacture of such thin-film semiconductor chips an a succession of active layers based on a III/V semiconductor compound material suitable to emit electromagnetic radiation is applied to a growth substrate. Since a growth substrate matched to the III/V semiconductor compound material usually absorbs some of the radiation generated by the active layers, the active layers is separated from the growth substrate an applied to a different carrier to increase the available light. The bond between the active layers and the carrier is created by gluing or soldering.

Located between the carrier and the active layers is a succession of reflective layers. The succession of reflective layers is designed to direct electromagnetic radiation to the radiation-emitting front side of the thin-film semiconductor chip thus increasing the radiation yield of the chip. As a rule, the succession of reflective layers includes at least one dielectric layer.

As described in publication DE 10 2004 004 780 A1, for example, the dielectric layer is photo-lithographically restructured to create openings in the dielectric layer to the reverse of the succession of active layers for reverseside contacting.

Subsequently, a metal film is attached, which fills the openings and connects them to each other, so that the reverse of the succession of active layers exhibits contact points, which are conductively interconnected.

The metallic layer generally contains Au and at least one doping material like Zn. By tempering the metallic layer the doting material is diffused into the H1/V semiconductor compound material. If the appropriate doping material is selected, a larger number of charge carriers is generated in the III/V semiconductor compound material at the boundary to the metallic layer, resulting in an electric contact point with generally uniform (ohmic) characteristics.

Publication DE 10046 170 A1 also describes a process, in which electrically conductive contact points of a solar cell through a passivating layer are generated with a laser.

### SUMMARY

This invention has the objective to introduce a simplified process for the manufacture of a thin-film semiconductor chip and in particular the electrically conductive contact points of the succession of active layers.

The disclosure content of the patent claims is hereby expressly included into the description.

A process for the manufacture of a thin-film semiconductor chip based on an III/V semiconductor compound material capable of generating electromagnetic radiation includes the following steps:

Application of an succession of active layers capable of generating electromagnetic radiation onto a growth substrate with a front side facing the growth substrate and reverse facing away from the growth substrate,
Application of at least one dielectric layer as part of a succession of reflective layers onto the reverse on the succession of active layers,
Using a laser to introduce energy into defined, restricted volume sections of the dielectric layer resulting in at least one opening toward the reverse of the succession of active layers,
Application of at least one metallic layer as additional part of the succession of reflective layers, so that the opening is at least partially filled with metallic material and at least one electrically conductive contact point to the reverse side of the active layer is being created,
Application of a carrier on the succession of reflective layers, and
Removal of the growth substrate.

The succession of reflective layers between the active series of successive layers and the carrier includes at least one dielectric and one metallic layer, whereby the dielectric layer contains SiNₓ and the metallic layer Au and Zn, for example. The dielectric layer may also include phospho-silicate glass, whereby such dielectric layer with phospho-silicate glass is preferably encapsulated by another encapsulation layer, which may include silicon nitride to largely prevent moisture from forming at the phospho-silicate layer resulting in phosphoric acid. Such type of reflective layer system for application onto a III/V semiconductor compound material is described in DE 10 2004 040 277.9 the disclosure content of which is hereby included by reference.

Since the succession of reflective layers includes at least one dielectric layer at least one contact point through the succession of reflective layers toward the reverse of the active succession of the layers is required.

Pursuant to the process, the opening inside the dielectric layer toward the reverse of the succession of active layers, in which subsequently an electrically conductive contact point is being formed, is created by laser. This provides the advantage that photolithographic processes, which usually are time and cost-intensive, can be reduced in the manufacture of thin-film semiconductor chips. This process furthermore advantageously allows contact points of a very small width since the laser is capable of creating smaller structures than photolithographic processes.

The reflective layer system may include in addition to the dielectric layer and the metallic layer additional layers. They may be layer for the encapsulation of the dielectric or the metallic layer or layer that provide adhesion between individual layers of the reflective layer series.

Usually, a laser can burn openings through these layers as well and create an electrical contact point inside these openings toward the reverse of the succession of active layers.

In a preferred embodiment of the process the contact point on the reverse is tempered in a subsequent step. The tempering of the electrically conductive contact point allows atoms from the metallic material of the contact point to diffuse into the III/V semiconductor compound material on the reverse. By choosing the appropriate metallic material based on the III/V semiconductor compound material, an electrically conductive contact point to the III/V semiconductor compound material with largely uniform characteristics can be manufactured.

Especially preferred is the tempering of the electrically conductive contact point at the reverse with a laser.

The use of a laser allows the introduction of the energy into targeted areas of the thin-film semiconductor chip only. In particular, the energy can be introduced locally at the boundary to the III/V semiconductor compound material. A process for the finishing of surfaces with the help of a laser is described in DE 10141352.1, whose disclosure content is included by reference. This embodiment of the process offers the advantage that in order to create electrical contact points with largely uniform (ohmic) characteristics only those locally limited areas of the chip requiring the treatment are exposed to increased temperatures.

This advantageously prevents other areas of the semiconductor chip from being exposed to higher temperatures during the tempering process, thus preventing metal atoms from diffusing into area where they are not wanted.

If, for example, the metallic layer of the succession of reflective layers includes different types of metals, one of which is less reflective than the other and if these two metals separate during the tempering process due to different diffusive characteristics, then the metal atoms with the less reflective characteristics may accumulate and therefore reduce the reflectivity of the reflective layer series.

As a sample of this situation let's look at a succession of reflective layers on a p-doped III/V semiconductor compound material, which includes a dielectric layer and a metallic layer, whereby the metallic layer contains Au and Zn. Au exhibits excellent reflectivity for electromagnetic radiation in the red spectrum of visible light. Zn, on the other hand, is able to easily diffuse into the p-doped III/V bonding semiconductor metal thus providing largely uniform characteristics to the electrically conductive contact point. When parts of the reflective layer series are exposed to high temperatures the Zn atoms may also migrate to the boundary of the dielectric layer. Since Zn exhibits less reflectivity in comparison to Au especially in the area of electromagnetic radiation in the red spectrum of the visible light, it reduces the quality of the reflective layers for red light.

In non-localized tempering processes, metal atoms may also migrate into the succession of active layers. There, they are usually imperfections promoting the non-radiating recombination of photons, thereby reducing the efficiency of the thin-film semiconductor chip. In order to prevent this, the succession of active layers usually exhibits a sufficiently thick layer of non-active III/V bonding

semiconductor material. When the contact is locally tempered with a laser as described in the invention, the thickness of this non-active III/V semiconductor compound material and therefore the thickness of the thin-film semiconductor chip can be advantageously reduced.

Another process for the manufacture of a thin-film semiconductor chip based on a III/V semiconductor compound material capable of generating electromagnetic radiation includes in particular the following steps:

Application of a succession of active layers capable of generating electromagnetic radiation on a growth substrate with a front side facing the growth substrate and a reverse side facing away from the growth substrate,
Creation of a succession of reflective layers including at least one metallic layer and at least one dielectric layer on the reverse the succession of active layers,
Introduction of energy by laser in at least one defined volume section of the succession of reflective layers so that inside the defined volume section at least one electrically conductive contact point to the reverse side of the succession of active layers is being created, and
Removal of the growth substrate.

In this process and in contrast to patent claim 1 the layers of the reflective succession are applied consecutively and afterward inserted into confined volume sections of the succession of reflective layers with a laser.

The laser heats the dielectric layer and the metallic area causing the dielectric layer to disintegrate or melt or both. The locally melted material of the metallic layer is therefore capable of creating an electrically conductive contact point to the reverse of the succession of active layers.

This process offers the same advantages as the process pursuant to patent claim 1. Furthermore, this process offers the advantage that the contact point usually does not need to be tempered since the energy is introduced locally at the boundary to the III/V semiconductor compound material so that while the contact point is being created, metal atoms can diffuse into the III/V semiconductor compound material.

In an additional embodiment of the process for the manufacture of a thin-film semiconductor chip based on a III/V semiconductor compound material capable of generating electromagnetic radiation includes in particular the following steps:

Application of a succession of active layers capable of generating electromagnetic radiation onto a growth substrate with a front side facing the growth substrate and a reverse side facing away from the growth material,
Application of at least one metallic reflective layer creating an electrically conductive contact point to the reverse of the succession of active layers,
Tempering of the electrically conductive contact point located at the reverse with a laser,
Application of a carrier on the succession of reflective layers, and
Removal of the growth substrate.

In contrast to some of the processes described herein, in this process no dielectric layer is applied between the reverse side of the active layers to be contacted and the reflecting layer. However, it is conceivable for additional layers to be located between metallic layers and the reverse side of the succession of active layers like a bonding layer, for example. Pursuant to this embodiment, the electric contact point is tempered with a laser to obtain a contact point with largely uniform (ohmic) characteristics.

This process offers the advantage that exposure of the entire semiconductor chip to high temperatures for the tempering of the reverseside contact, especially the succession of active layers, can be avoided.

In a preferred embodiment of all three processes a succession of tempered finishing layers is applied to the front of the active layer succession, which includes at least one dielectric layer. Subsequently, at least one metallic layer is at least partially applied to the tempered succession of layers and laser energy is introduced in confined volume sections of the succession of finishing layers and the metallic layer, so that at least one electrically conductive contact point to the front side of the succession of active layers is created.

The succession of finishing layers may contain a dielectric layer, including glass, and which may be structured in such fashion that the extraction of electromagnetic radiation at the front side of the thin-film semiconductor chip is improved. A succession of finishing layers may have an additional or exclusive protective or passivating function.

The front side contact points through a succession of finishing layers containing at least one dielectric layer toward the front side of the succession of active layers are created analogous to the creation of reverse side contact points pursuant to patent claim 4 by a succession of reflecting layers containing one dielectric layer. By introducing energy into confined volume sections of the metallic layer and the finishing layers with a laser, the dielectric layer is locally disintegrated or melted or both and the locally melted material of the metallic layer creates an electrically conductive contact point to the front side of the succession of active layers. The creation of front side contact points with a laser provides the same advantages as the above-described advantages as laser-created reverse-side contacts.

Conventional tempering processes for the tempering of front-side contacts, in which not only locally confined volume sections of the semiconductor chip are exposed to increased temperatures but rather the entire chip, present the problem that the tempering temperature is limited by the temperature resistance of the joining materials between the active layers and carriers. This causes the chips in non-local tempering processes usually to be exposed to lower temperatures are would be required for contact creation. This problem can be advantageously bypassed if the contact does not require any post-tempering.

If the dielectric layer is located on the front side of the succession of active layers as part of a succession of finishing layers then a contact point through the finishing layer may also be provided by creating at least one opening through the finishing layer with the help of a laser. Applied to this layer—as with the process pursuant to patent claim 1—is a metallic layer, which fills the opening with metallic material and thus creates an electrically conductive contact point to the front side of the succession of active layers.

Furthermore, both processes can be used to first apply at least one electrically conductive contact on the front side of the succession of active layers, which is subsequently laser-tempered. This embodiment also advantageously prevents exposure of the entire chip to high temperatures for the tempering of the contacts.

At this point it shall be pointed out that the above-described processes for the manufacture of a front-side contact can be applied independently of the manufacturing processes of the remaining part of the thin-film semiconductor chip.

All three processes are especially well suited for the manufacture of thin-film light-emitting diode chips.

A thin-film light-emitting diode chip has in particular the following characteristics:

Applied a main surface of a radiation-emitting succession of epitaxy layers facing a carrier element is a reflective layer or a succession of layers, which reflect at least part of the electromagnetic radiation generated in the epitaxy layers reverse into them; and
The succession of epitaxy layers exhibits a thickness in a range of 20 μm or less, especially in the range of 10 μm.

The epitaxy layers preferably contain at least one semiconductor layer with at least one surface exhibiting a mixed structure, which in the ideal case results in a nearly ergodic distribution of the light within the succession of epitaxy layers, i.e. which preferably exhibits ergodic stochastic distribution characteristics.

One basic principle of thin-film semiconductor chips is described, for example, in publication I. Schnitzer at al., Appl. Phys. Lett. 63 (16), 18 Oct. 1993, 2174-2176, the disclosure content of which is hereby included by reference.

As a rule, the reverseside of a thin-film light-emitting chip contains a p-doped III/V semiconductor compound material and the front side contains an n-doped III/V semiconductor compound material. However, a reverse configuration is conceivable as well.

If the side with the succession of active layers, on which the contact is applied, is a p-doped phosphide III/V semiconductor compound material, then the contact point preferably contains at least one of the elements Au and Zn.

Preferably, the phosphide III/V semiconductor compound material is AlₙGaₘIn₁₋ₙ₋ₘP, wherein 0≦n≦1, 0≦m≦1 and n+m≦1, independent of the type of doping. The material is not required to exhibit the mathematically exact composition of the above-mentioned formula. It may rather exhibit one or multiple doping materials as well as additional components, which basically do not change the typical physical characteristics of the AlₙGaₘIn₁₋ₙ₋ₘP material. For reasons of simplification the above formula only includes the basic components of the crystal lattice (Al, Ga, In, P) even though they may partially be substituted by small amounts of other materials.

Au is a material with good reflective characteristics for electromagnetic radiation with wavelengths in the red range of visible light. Zn diffuses during the tempering of the contact into the p-doped phosphide III/V semiconductor compound material and there preferably populates group III lattice sites while generating holes. This increases the number of charge carriers (holes), which usually leads to better characteristics of the electrical contact.

If the side of the succession of active layers, where the contact is applied, exhibits an n-doped phosphide III/V semiconductor compound material, then the contact preferably contains at least one of the elements Au and Ge.

In this case as well Au is used as contact material due to its good reflective characteristics. During the tempering of the contact Ge preferably again occupies lattice sites of the group III superlattice and increases the number of electrons in this area.

If the active layer side, on which the contact is applied, contains p-doped nitride III/V semiconductor compound material, then the contact area preferably exhibits at least one of the elements Pt, Rh, Ni, Au, Ru, Pd, Re and Ir.

The nitride III/V semiconductor compound material is preferably AlₙGaₘIn₁₋ₙ₋ₘN, wherein 0≦n≦1, 0≦m≦1 and n+m≦1, independent of the doping.

The material is not required to exhibit the mathematically exact composition of the above-mentioned formula. It may rather exhibit one or multiple doping materials as well as additional components, which do not change the typical physical characteristics of the AlₙGaₘIn₁₋ₙ₋ₘN material significantly. For reasons of simplification the above formula only includes the basic components of the crystal lattice (Al, Ga, In, N) even though they may partially be substituted by small amounts of other materials.

If the active layer side, to which the contact is applied, contains a n-doped nitride III/V semiconductor compound material, then the contact area preferably exhibits at least one of the elements Ti, Al, and W.

If the active layer side, to which the contact is applied, contains a phosphide III/V semiconductor compound material, then this side may in addition to or as alternative to the phosphide III/V semiconductor compound material also include an arsenide III/V semiconductor compound material. The materials, which depending on the doping type, are preferably used for the contacts are usually not different from the ones named above.

If the active layer side, to which the contact is applied, contains a nitride III/V semiconductor compound material, then this side may in addition to the nitride III/V semiconductor compound material also include an arsenide III/V semiconductor compound material. Here too, the materials, which depending on the doping type, are preferably used for the contacts are usually not different from the ones named above.

Preferably, the arsenide III/V semiconductor compound is of the formula AlₙGaₘIn₁₋ₙ₋ₘAs, wherein 0≦n≦1, 0≦m≦1, and n+m≦1, independent of the type of doping.

The material is not required to exhibit the mathematically exact composition of the above-mentioned formula. It may rather exhibit one or multiple doping materials as well as additional components, which do not change the typical physical characteristics of AlₙGaₘIn₁₋ₙ₋ₘAs significantly. For reasons of simplification the above formula only includes the basic components of the crystal lattice (Al, Ga, In, As) even though they may partially be substituted by small amounts of other materials.

Other advantages and preferred embodiments result from the description of the two embodiments in connection with FIGS. 1a to 1f, 2a to 2b, 3a to 3b, 4a to 4c, and 5a to 5d.

### BRIEF DESCRIPTION OF THE FIGURES

FIGS. 1a to 1f are schematic representations of different processing stages of a first embodiment pursuant to one of the processes,

FIGS. 2a to 2b are schematic representations of additional processing stages of the first embodiment according to one of the processes,

FIGS. 3a to 3b are schematic representations of two processing stages of a second embodiment pursuant to one of the processes,

FIGS. 4a to 4c are schematic representations of additional processing stages of the second embodiment pursuant to one of the processes, and FIGS. 5a to 5d are schematic representations of additional processing stages of a third embodiment pursuant to one of the processes.

### DETAILED DESCRIPTION

In the embodiments and figures, identical or identically functioning components are referenced by identical markers. The elements shown in the figures, especially the thicknesses of layers are not true to scale but may in some cases be exaggerated for better understanding.

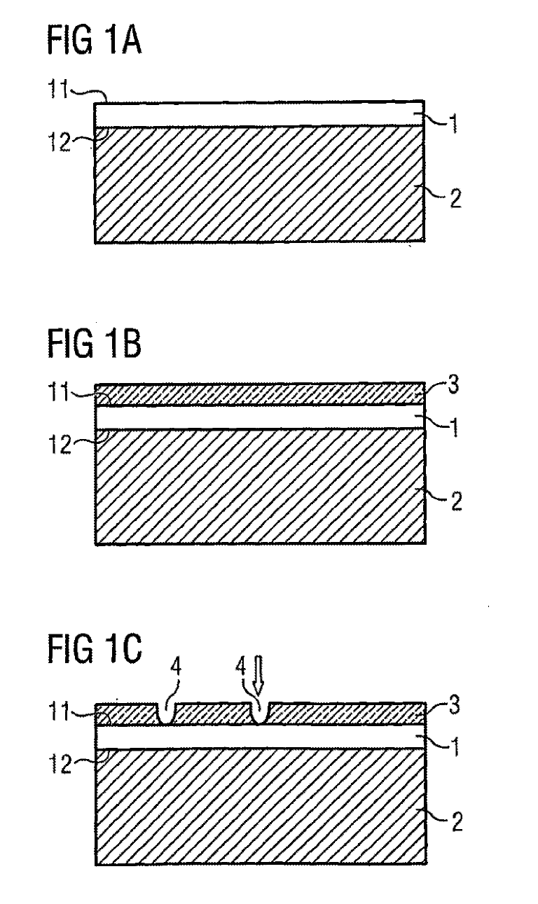

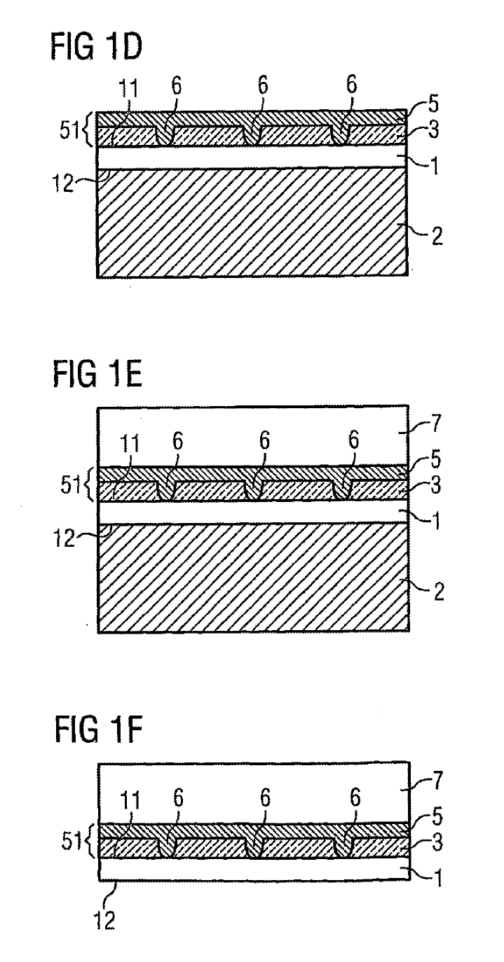

In the embodiment pursuant to FIGS. 1a to 1f, a succession of active layers 1 based on a III/V semiconductor compound is epitaxially applied to a growth substrate 2 to create a thin-film LED chip. The side of the active layers 1 facing the growth substrate 2 is called the front side 12 and the side of the active layers 1 opposite the front side 12 is called the reverse side 11. The active layers 1 are capable of emitting electromagnetic radiation and exhibit a radiation-generating pn-junction or a radiation-emitting simple or multiple quantum well structure. Such structures are known to the professional and are therefore not explained in further detail. The active layer succession 1 includes AlGaInP or GaInN, wherein the front side 12 of the active layers 1 is n-doped and the reverse side 11 p-doped. If a succession of active layers 1 based on a nitride III/V semiconductor compound shall be grown epitaxially, the material to be used for the growth substrate 2 may be GaN, SiC, or sapphire. An appropriate growth substrate 2 for the epitaxial growth of a succession of active layers 1 based on a phosphide III/V semiconductor compound may be GaAs.

Applied subsequently to the succession of active layers 1 is a dielectric layer 3, which may include SiNₓ. A laser is used to insert puncture openings 4 in the dielectric layer 3 thereby exposing the reverse side 11 of the active layers 1 inside these openings 4. As a rule, these openings 4 exhibit a diameter of 1 μm to 20 μm so that in the subsequent process steps a contact 6 with a diameter of the same size is created.

In a next step, a metallic layer 5 is subsequently applied to the dielectric layer 3, for example by vaporization or sputtering. The dielectric layer 3 and the metallic layer 5 together form a reflective layer 51. In the event that the reverse side 11 of the active layers 1 contains a p-doped phosphide III/V semiconductor compound, e.g. AlGaInP, the metallic layer 5 will preferably contain gold and Zn. However, if the reverse side 11 of the active layers contains a p-doped nitride III/V semiconductor compound like GaInN, then the metallic layer 5 preferably contains Pt, Rh, Ni, Au, Ru, Pd, Re or Ir.

As the metallic material is applied the openings 4 are filled and connected with metallic material so that electrically conductive contacts 6 to the reverse side 11 of the succession of the active layers 1 are created, which are electrically conductive interconnected.

In order to obtain a contact 6 with largely uniform (ohmic) characteristics the contact is subsequently tempered. For this purpose the entire chip may be inserted into an oven or the chip may be exposed to an ambient temperature of 450° C.

Preferably, the contacts 6 will be tempered locally with a laser. The tempering of electrical contacts 6 using a laser is described in publication DE 101413521, the contents of which is hereby included by reference.

If the reverse and front contacts 6 shall contain different metallic materials then multiple layers containing the desired metallic materials may be applied. In this case, the layers would preferably be very thin. After the reverse electric contacting of the active layers 1a carrier 7 is applied to the metallic layer 5 with adhesive or solder. In a subsequent step the growth substrate 2 is removed.

For the electric contacting of the front side of the active layers 1 here as well an electrical contact 6 made of a metallic material is applied to the front sides 12 of the succession of active layers 1. If the front side 12 of the succession of active layers 1 contains an n-doped phosphide III/V semiconductor compound like AlGaInP then the metallic material generally contains Au and Ge. If the front side 12 contains an n-doped nitride III/V semiconductor compound like GaInN then the metallic material preferably contains Ti, Al, or W. Like the reverse contact site 6 the front contact site 6 is also tempered, also preferably with a laser.

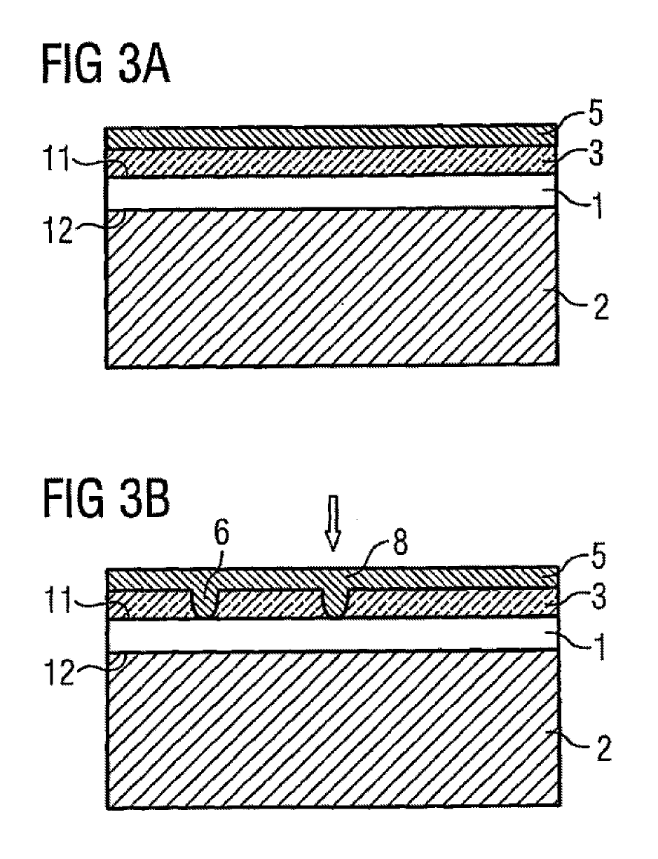

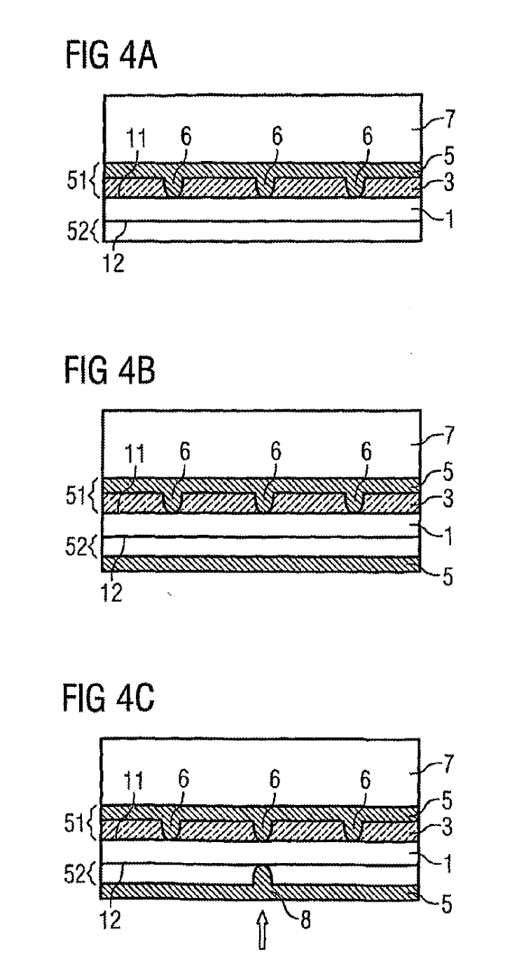

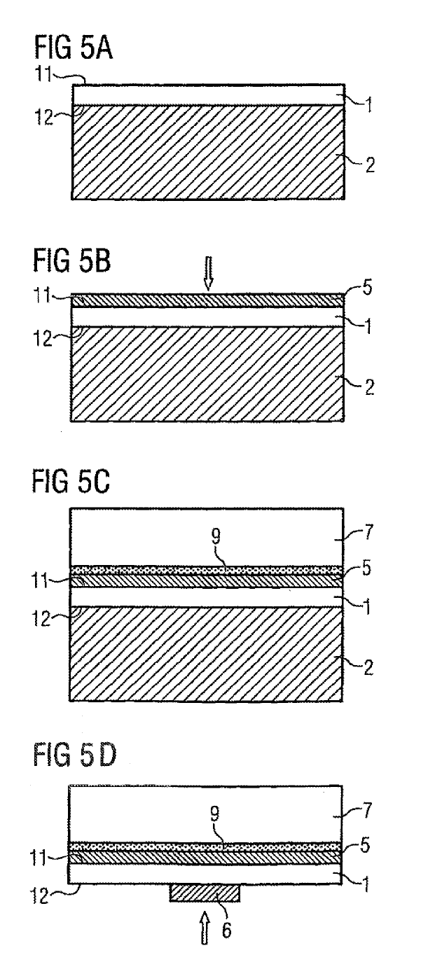

In a further embodiment of the process pursuant to FIGS. 3a, 3b and 4a to 4c for the reverse contacting of the succession of active layers 1 a metallic layer 5 is applied to the dielectric layer 3 after the dielectric layer 3 has been applied to the succession of active layers 1.

In a subsequent step, point-sized areas 8 of the dielectric layer 3 and the metallic area 5 are heated with a laser. This causes the material of the dielectric layer 3 to disintegrate or evaporate at least partially, and the material of the metallic layer 5 melts in this area, so that electrically conductive contact points 6 with largely uniform (ohmic) characteristics to the reverse side 11 of the succession of active layers 1 are created. At this point, as pursuant to the first embodiment, a carrier 7 is applied to the metallic layer 5, and the growth substrate is removed.

The front side contact points 6 can now be applied as described for the first embodiment.

If the front side 12 of the succession of active layers 1 contains one or more dielectric layers 3 as part of a finished succession of layers 52, which may be designed to protect the active layers 1 or to enhance the extraction of electromagnetic radiation from the chip, then the electrically conductive contact point 6 may be preferably applied to the front side 12 of the succession of active layers 1 like the reverse side contact point 6 pursuant to the second embodiment. In this case, again a metallic layer 5 is applied to the dielectric layer 3 and laser energy is introduced to point-sized areas 8 inside the one or multiple dielectrical layer(s) 3 and the metallic layer 5. This causes the material of the dielectric layer 3 to at least partially disintegrate and the material of the metallic layer 5 to melt in this area, so that an electrically conductive contact point 6 with largely uniform (ohmic) characteristics to the front side 12 of the succession of active layers is created.

As in the embodiment pursuant to FIGS. 1a to 1d, in the embodiment pursuant to FIGS. 5a to 5d again a succession of active layers 1 is applied to a growth substrate 2, which is capable of emitting electromagnetic radiation (see FIG. 5a). Deviating from the above-described embodiments a metallic reflective layer 5, e.g. Ag, is subsequently applied to the reverse side 11 of the active layers 1, which is not separated from the active layers 1 by a dielectric layer 3.

In this case, the metallic layer 5 constitutes the electrical contact point 6 to the reverse side 11 of the succession of active layers 1.

Configured between the metallic layer 5 and the reverse side 11 of the active layers 1 may be another layer, e.g. for adhesive purposes. Such adhesive layer is usually very thin and has a thickness of only a few nanometers.

In order to obtain largely uniform (ohmic) characteristics of the electrical contact 6 between the metallic layer 5 and the reverse side 11 of the succession of active layers 1, the metallic layer 5 is laser tempered as shown in FIG. 5b.

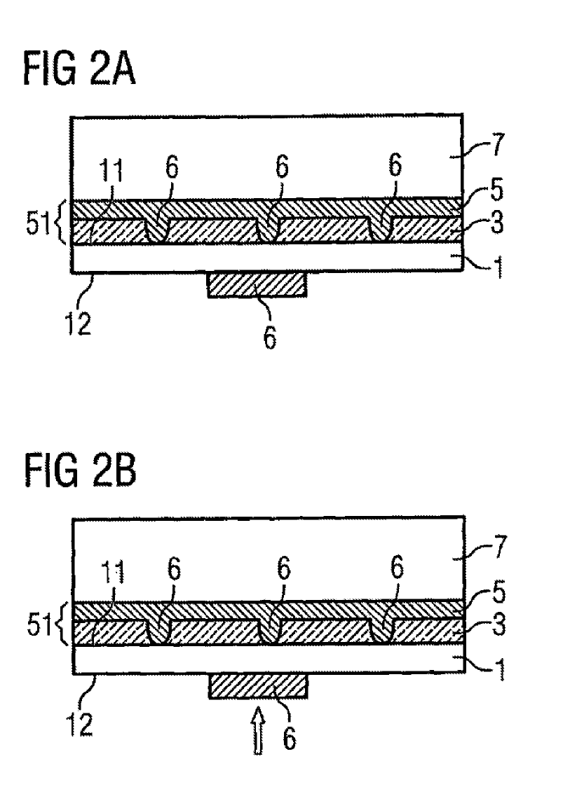

In a subsequent step, as already described, a carrier 7 is attached to the reverse side 11 of the succession of active layers 1, e.g. using a joint layer 9 containing glue or solder (compare FIG. 5c). The growth substrate 2 is then removed and an electrical contact 6 to the front side 12 of the of succession of active layers 1 is applied. This electrical contact 6 on the front side may be applied as already for the embodiments pursuant to FIGS. 2a and 2b or FIGS. 4a to 4c.

This patent application claims the priorities of German patent applications 10 2004 047392.7 and 10 2004 061865.8, the disclosure content of which is hereby included by reference.

The description of the process based on the embodiments shall, of course, not be interpreted as a limitation of the invention. The invention especially includes any new features or combination of features, especially including any combination of the features in the patent claims, even if this combination is not expressly indicated in the patent claims.

1.-12. (canceled)

13. A method of manufacturing a III/V thin-film semiconductor chip, comprising:
forming a plurality of active layers capable of generating electromagnetic radiation onto a growth substrate, wherein the plurality of active layers has a front side that faces the growth substrate and a reverse side that faces away from the growth substrate;
forming a dielectric layer on the reverse side of the plurality of active layers;
directing energy into a defined section of the dielectric layer using a laser to create an opening in the dielectric layer and to expose the plurality of active layers;
applying a metallic layer in the opening to create an electrically conductive contact point on the reverse side of the plurality of active layers, wherein the dielectric layer and metallic layer form a reflective stack;
applying a carrier on the reflective stack; and
removing the growth substrate.

14. The method of claim 13, further comprising tempering the contact point.

15. The method of claim 14, wherein tempering includes tempering with energy from a laser.

16. The method of claim 13, further comprising:
applying a finishing layer to the front side of the plurality of active layers, wherein the finishing layer includes a dielectric layer;
applying at least a portion of a metallic layer to the finishing layer; and
directing energy into a laterally defined volumetric section of the finishing layer and the metallic layer using a laser to form a front-side electrically conductive contact point to the front side of the plurality of active layers.

17. The method of claim 13, further comprising:
forming a front-side electrically conductive contact point to the front side of the plurality of active layers; and
tempering the front-side electrically conductive contact point with laser energy.

18. The method of claim 17, wherein:
the front side of the plurality of active layers includes a p-doped phosphide III/V semiconductor compound material or a p-doped arsenide III/V semiconductor compound material; and
the front-side electrically conductive contact point includes at least one of the elements gold or zinc.

19. The method of claim 17, wherein:
the front side of the plurality of active layers includes an n-doped phosphide III/V semiconductor compound material or an n-doped arsenide III/V semiconductor compound material; and
the front-side electrically conductive contact point includes at least one of the elements gold or germanium.

20. The method of claim 17, wherein:
the front side of the plurality of active layers includes a p-doped nitride III/V semiconductor compound material; and
the front-side electrically conductive contact point contains at least one of platinum, rhodium, nickel, gold, ruthenium, palladium, rhenium or iridium.

21. The method of claim 17, wherein:
the front side of the plurality of active layers includes an n-doped nitride III/V semiconductor compound material; and
the front-side electrically conductive contact point includes at least one of the elements titanium, aluminum or tungsten.

22. The method of claim 13, wherein:
the reverse side of the plurality of active layers includes a p-doped phosphide III/V semiconductor compound material or a p-doped arsenide III/V semiconductor compound material; and
the contact point includes at least one of the elements gold or zinc.

23. The method of claim 13, wherein:
the reverse side of the plurality of active layers includes an n-doped phosphide III/V semiconductor compound material or an n-doped arsenide III/V semiconductor compound material; and
the contact point includes at least one of the elements gold or germanium.

24. The method of claim 13, wherein:
the reverse side of the plurality of active layers includes a p-doped nitride III/V semiconductor compound material; and
the contact point contains at least one of platinum, rhodium, nickel, gold, ruthenium, palladium, rhenium or iridium.

25. The method of claim 13, wherein:
the reverse side of the plurality of active layers includes an n-doped nitride III/V semiconductor compound material; and
the contact point includes at least one of the elements titanium, aluminum or tungsten.

26. A method of forming a thin-film III/V semiconductor chip, comprising:
forming a plurality of active layers capable of generating electromagnetic radiation on a growth substrate, wherein the plurality of active layers has a front side adjacent to the growth substrate and a reverse side that faces away from the growth substrate;
forming a plurality of reflective layers on a reverse side of the plurality of active layers, wherein the plurality of reflective layers includes a metallic layer and a dielectric layer;
directing energy into a defined volumetric section of the plurality of reflective layers using a laser to create an electrically conductive contact point on the reverse side of the plurality of active layers;
applying a carrier onto the plurality of reflective layers; and
removing the growth substrate from the plurality of active layers.

27. The method of claim 26, further comprising:
applying a finishing layer to the front side of the plurality of active layers, wherein the finishing layer includes a dielectric layer;
applying at least a portion of a metallic layer to the finishing layer; and
directing energy into a laterally defined volumetric section of the finishing layer and the metallic layer using a laser to form a front-side electrically conductive contact point to the front side of the plurality of active layers.

28. The method of claim 26, further comprising:
forming a front-side electrically conductive contact point to the front side of the plurality of active layers; and
tempering the front-side electrically conductive contact point with laser energy.

29. The method of claim 28, wherein:
the front side of the plurality of active layers includes a p-doped phosphide III/V semiconductor compound material or a p-doped arsenide III/V semiconductor compound material; and
the front-side electrically conductive contact point includes at least one of the elements gold or zinc.

30. The method of claim 28, wherein:
the front side of the plurality of active layers includes an n-doped phosphide III/V semiconductor compound material or an n-doped arsenide III/V semiconductor compound material; and
the front-side electrically conductive contact point includes at least one of the elements gold or germanium.

31. The method of claim 28, wherein:
the front side of the plurality of active layers includes a p-doped nitride III/V semiconductor compound material; and
the front-side electrically conductive contact point contains at least one of platinum, rhodium, nickel, gold, ruthenium, palladium, rhenium or iridium.

32. The method of claim 28, wherein:
the front side of the plurality of active layers includes an n-doped nitride III/V semiconductor compound material; and
the front-side electrically conductive contact point includes at least one of the elements titanium, aluminum or tungsten.

33. The method of claim 26, wherein:
the reverse side of the plurality of active layers includes a p-doped phosphide III/V semiconductor compound material or a p-doped arsenide III/V semiconductor compound material; and
the contact point includes at least one of the elements gold or zinc.

34. The method of claim 26, wherein:
the reverse side of the plurality of active layers includes an n-doped phosphide III/V semiconductor compound material or an n-doped arsenide III/V semiconductor compound material; and
the contact point includes at least one of the elements gold or germanium.

35. The method of claim 26, wherein:
the reverse side of the plurality of active layers includes a p-doped nitride III/V semiconductor compound material; and
the contact point contains at least one of platinum, rhodium, nickel, gold, ruthenium, palladium, rhenium or iridium.

36. The method of claim 26, wherein:
the reverse side of the plurality of active layers includes an n-doped nitride III/V semiconductor compound material; and
the contact point includes at least one of the elements titanium, aluminum or tungsten.

37. A method of forming a thin-film III/V semiconductor chip, comprising:
forming a plurality of active layers capable of generating electromagnetic radiation on a growth substrate, wherein the plurality of active layers have a front side adjacent to the growth substrate and a reverse side that faces away from the growth substrate;
forming a metallic reflective layer on a reverse side of the plurality of active layers to create a contact point;
tempering the contact point with laser energy;
applying a carrier on the metallic reflective layer; and
removing the growth substrate from the active layers.

38. The method of claim 37, further comprising:
applying a finishing layer to the front side of the plurality of active layers, wherein the finishing layer includes a dielectric layer;
applying at least a portion of a metallic layer to the finishing layer; and
directing energy into a laterally defined volumetric section of the finishing layer and the metallic layer using a laser to form a front-side electrically conductive contact point to the front side of the plurality of active layers.

39. The method of claim 37, further comprising:
forming a front-side electrically conductive contact point to the front side of the plurality of active layers; and
tempering the front-side electrically conductive contact point with laser energy.

40. The method of claim 39, wherein:
the front side of the plurality of active layers includes a p-doped phosphide III/V semiconductor compound material or a p-doped arsenide III/V semiconductor compound material; and
the front-side electrically conductive contact point includes at least one of the elements gold or zinc.

41. The method of claim 39, wherein:
the front side of the plurality of active layers includes an n-doped phosphide III/V semiconductor compound material or an n-doped arsenide III/V semiconductor compound material; and
the front-side electrically conductive contact point includes at least one of the elements gold or germanium.

42. The method of claim 39, wherein:
the front side of the plurality of active layers includes a p-doped nitride III/V semiconductor compound material; and
the front-side electrically conductive contact point contains at least one of platinum, rhodium, nickel, gold, ruthenium, palladium, rhenium or iridium.

43. The method of claim 39, wherein:
the front side of the plurality of active layers includes an n-doped nitride III/V semiconductor compound material; and
the front-side electrically conductive contact point includes at least one of the elements titanium, aluminum or tungsten.

44. The method of claim 37, wherein:
the reverse side of the plurality of active layers includes a p-doped phosphide III/V semiconductor compound material or a p-doped arsenide III/V semiconductor compound material; and
the contact point includes at least one of the elements gold or zinc.

45. The method of claim 37, wherein:
the reverse side of the plurality of active layers includes an n-doped phosphide III/V semiconductor compound material or an n-doped arsenide III/V semiconductor compound material; and
the contact point includes at least one of the elements gold or germanium.

46. The method of claim 37, wherein:
the reverse side of the plurality of active layers includes a p-doped nitride III/V semiconductor compound material; and
the contact point contains at least one of platinum, rhodium, nickel, gold, ruthenium, palladium, rhenium or iridium.

47. The method of claim 37, wherein:
the reverse side of the plurality of active layers includes an n-doped nitride III/V semiconductor compound material; and
the contact point includes at least one of the elements titanium, aluminum or tungsten.
